(19) United States
(12) Patent Application Publication
(10) Pub. No.: US 2025/0374725 A1
(43) Pub. Date: Dec. 4, 2025

(54) DISPLAY DEVICE USING LIGHT EMITTING ELEMENTS AND MANUFACTURING METHOD THEREFOR

(71) Applicant: LG ELECTRONICS INC., Seoul (KR)

(72) Inventor: Byungjoon RHEE, Seoul (KR)

(73) Assignee: LG ELECTRONICS INC., Seoul (KR)

(21) Appl. No.: 18/868,591

(22) PCT Filed: May 31, 2022
(86) PCT No.: PCT/KR2022/007751

§ 371 Date: Nov. 22, 2024

(51) Int. Cl. H10H 29/03; H01L 21/56; H01L 23/00; H10H 29/01

(52) U.S. Cl. CPC H10H 29/03; H01L 21/561; H01L 24/81; H01L 24/96; H01L 24/97; H10H 29/0364; H01L 2224/81191; H01L 2224/81192; H01L 2224/81203; H01L 2224/96; H01L 2224/97

(57) ABSTRACT

The present disclosure can be applied to technical fields relating to display devices, and relates to a display device using, for example, micro light emitting diodes (LEDs), and a manufacturing method therefor. The present disclosure comprises the following steps: preparing an assembly in which a shock-absorbing layer is formed on a wiring substrate in which electrode pads are formed; positioning light emitting elements arranged on a base substrate at the locations of the electrode pads on the assembly; transferring the light emitting elements onto the shock-absorbing layer; and bonding the light emitting elements to the electrode pads.

### TECHNICAL FIELD

The present disclosure relates to a technical field related to a display device, for example, a display device using a micro light emitting diode (LED) and a manufacturing method thereof.

### BACKGROUND ART

Recently, in a field of a display technology, display devices having excellent characteristics such as thinness, flexibility, and the like are developed. On the other hand, currently commercialized major displays are represented by LCDs (liquid crystal displays) and OLEDs (organic light emitting diodes).

However, in the case of LCDs, there are problems, such as a non-fast response time and difficulty in implementing flexibility, and in the case of OLEDs, there are problems, such as a short lifespan and a poor mass production yield.

On the other hand, light emitting diodes (LEDs) are semiconductor light emitting elements well known as converting current into light, and starting with commercialization of red LEDs using GaAsP compound semiconductors in 1962, they are used as light sources for display images in electronic devices including information and communication devices along with GaP: N-based green LEDs. Therefore, a solution to solve the above-described problems may be proposed by implementing displays using semiconductor light emitting elements. The semiconductor light emitting elements have various advantages, such as a long lifespan, low power consumption, excellent initial driving characteristics, and high vibration resistance, compared to filament-based light emitting elements.

The size of these semiconductor light emitting elements has recently been reduced to several tens of micrometers. Therefore, if a display device is implemented using these small-sized semiconductor light emitting elements, a very large number of semiconductor light emitting elements must be assembled on a wiring substrate of the display device.

However, in a process of assembling these light emitting elements, there is a problem in that it is very difficult to precisely locate a large number of semiconductor light emitting elements at desired positions of the wiring substrate. This problem is becoming more severe as high-resolution displays become more common.

For example, in a process of separating and transferring semiconductor light emitting elements formed on a growth substrate by a laser lift-off process, the number of transfers may be significantly increased.

In addition, since this transfer process is performed by contact between the semiconductor light emitting elements ad a wiring substrate or a temporary substrate, there may be various processes that need to be resolved, such as an alignment problem and a chip breakage problem.

Accordingly, a solution that can solve these problems is required.

### DISCLOSURE

### Technical Task

One technical task to be solved by the present disclosure is to provide a display device using light emitting elements, in which the light emitting elements located on a base substrate may be directly transferred onto a wiring substrate in a non-contact manner, and a manufacturing method thereof.

Another technical task to be solved by the present disclosure is to provide a display device using light emitting elements, in which high-precision alignment of the light emitting elements may be achieved during a transfer process, and a manufacturing method thereof.

In addition, another technical task to be solved by the present disclosure is to provide a display device using light emitting elements, in which the transfer process and electrical connection process of the light emitting elements are simplified so that a yield is improved, and a manufacturing method thereof.

In addition, another technical task to be solved by the present disclosure is to provide a display device using light emitting elements that are usable in display devices having all resolutions regardless of the pixel pitch of a display, and a manufacturing method thereof.

In addition, yet another technical task to be solved by the present disclosure is to provide a display device using light emitting elements that absorbs shock from the light emitting elements during a non-contact transfer process to prevent the light emitting elements from bouncing off and thus prevent damage to the light emitting elements, and a manufacturing method thereof.

### Technical Solutions

In order to solve the above technical tasks, a first aspect of the present disclosure provides a manufacturing method of a display device using light emitting elements including preparing an assembly comprising a wiring substrate on which electrode pads are formed, and a shock-absorbing layer which is formed on the wiring substrate, locating the light emitting elements arranged on a base substrate at positions of the electrode pads on the assembly, transferring the light emitting elements onto the shock-absorbing layer, and bonding the light emitting elements to the electrode pads.

As an exemplary embodiment, the light emitting elements may be electrically connected to the electrode pads by conductive balls.

As an exemplary embodiment, transferring the light emitting elements onto the shock-absorbing layer may include irradiating a laser on the light emitting elements from a base substrate side.

As an exemplary embodiment, an adhesive layer may be located between the electrode pads and the shock-absorbing layer.

As an exemplary embodiment, the shock-absorbing layer and the adhesive layer may have the same directional characteristics with respect to heat.

As an exemplary embodiment, the shock-absorbing layer may include a nano-fiber layer.

As an exemplary embodiment, the base substrate may include a growth substrate for the light emitting elements.

As an exemplary embodiment, the light emitting elements grown on the growth substrate may be blue or green light emitting elements.

As an exemplary embodiment, the base substrate may include a sacrificial layer to which the light emitting elements are attached.

As an exemplary embodiment, the sacrificial layer may include a UV absorbing layer.

As an exemplary embodiment, the light emitting elements attached to the sacrificial layer may be red light emitting elements.

As an exemplary embodiment, bonding the light emitting elements to the electrode pads may include applying heat and pressure.

In order to solve the above technical tasks, a second aspect of the present disclosure provides a manufacturing method of a display device using light emitting elements including preparing an assembly comprising a wiring substrate on which electrode pads is formed, and a shock-absorbing layer which is located on the wiring substrate, locating the light emitting elements arranged on a base substrate at positions of the electrode pads on the assembly, transferring the light emitting elements onto the shock-absorbing layer, locating an adhesive layer on the transferred light emitting elements, and bonding the light emitting elements to the electrode pads by applying pressure to the adhesive layer toward the light emitting elements.

As an exemplary embodiment, the light emitting elements may be electrically connected to the electrode pads by conductive balls located on the electrode pads.

As an exemplary embodiment, the assembly may comprise partition walls configured to support the shock-absorbing layer to space the shock-absorbing layer apart from the electrode pads.

### Advantageous Effects

According to one embodiment of the present disclosure, the following effects are provided.

First, according to the embodiment of the present disclosure, light emitting elements located on a base substrate may be directly transferred onto a wiring substrate. For example, in a state in which the light emitting elements are formed on a growth substrate, a so-called chip-on-wafer (COW) state, a transfer process may be performed once.

Therefore, a process of electrically connecting the light emitting elements to the wiring substrate may be performed immediately thereafter.

In addition, high-precision alignment of the light emitting elements may be achieved by this process.

In addition, since the transfer process and the electrical connection process of the light emitting elements are simplified, a yield may be improved. Accordingly, the manufacturing cost and production time of the display device may be significantly reduced.

This transfer process may be used for display devices having all resolutions regardless of the pixel pitch of a display. Here, a time for performing laser lift-off may be adjusted.

In addition, since the above-described transfer process may be performed in a non-contact manner, the interaction between materials is minimized, thereby enabling active response to improve a mass production yield.

This transfer process may be applied to all vertical, horizontal, and flip-chip light emitting elements. In addition, as described above, red light emitting elements may be attached to the base substrate and transferred under the same conditions as green and blue light emitting elements located on the growth substrate.

In addition, shock from the light emitting elements is absorbed in the non-contact transfer process, and thus the light emitting elements may be prevented from bouncing off, thereby preventing damage to the light emitting elements.

Furthermore, according to other embodiments of the present disclosure, there are additional technical effects not mentioned herein. Those skilled in the art may understood these effects through the entire meaning of the following description and drawings.

### DESCRIPTION OF DRAWINGS

FIG. 1 is a schematic cross-sectional view showing a transfer process of a first light emitting element in a manufacturing method of a display device according to a first embodiment of the present disclosure.

FIG. 2 is a schematic cross-sectional view showing a transfer process of a second light emitting element in the manufacturing method of the display device according to the first embodiment of the present disclosure.

FIG. 3 is a schematic cross-sectional view showing a transfer process of a third light emitting element in the manufacturing method of the display device according to the first embodiment of the present disclosure.

FIG. 4 is a schematic cross-sectional view showing a state in which the transfer of the light emitting elements is completed in the manufacturing method of the display device according to the first embodiment of the present disclosure.

FIG. 5 is a schematic cross-sectional view showing a process of bonding the light emitting elements in the manufacturing method of the display device according to the first embodiment of the present disclosure.

FIG. 6 is a schematic cross-sectional view showing a state in which the assembly of the light emitting elements is completed by the manufacturing method of the display device according to the first embodiment of the present disclosure.

FIG. 7 is a schematic cross-sectional view showing a transfer process of a first light emitting element in a manufacturing method of a display device according to a second embodiment of the present disclosure.

FIG. 8 is a schematic cross-sectional view showing a transfer process of a second light emitting element in the manufacturing method of the display device according to the second embodiment of the present disclosure.

FIG. 9 is a schematic cross-sectional view showing a transfer process of a third light emitting element in the manufacturing method of the display device according to the second embodiment of the present disclosure.

FIG. 10 is a schematic cross-sectional view showing a state in which the transfer of the light emitting elements is completed in the manufacturing method of the display device according to the second embodiment of the present disclosure.

FIG. 11 is a schematic cross-sectional view showing a process of bonding the light emitting elements in the manufacturing method of the display device according to the second embodiment of the present disclosure.

FIG. 12 is a schematic cross-sectional view showing a transfer process of a first light emitting element in a manufacturing method of a display device according to a third embodiment of the present disclosure.

FIG. 13 is a schematic cross-sectional view showing a state in which the transfer of the light emitting elements is completed in the manufacturing method of the display device according to the third embodiment of the present disclosure.

FIG. 14 is a schematic cross-sectional view showing a state in which an adhesive layer is placed in the manufacturing method of the display device according to the third embodiment of the present disclosure.

FIG. 15 is a schematic cross-sectional view showing a process of bonding light emitting elements in the manufacturing method of the display device according to the third embodiment of the present disclosure.

FIG. 16 is a schematic cross-sectional view showing a state in which the assembly of the light emitting elements is completed by the manufacturing method of the display device according to the third embodiment of the present disclosure.

FIG. 17 is a schematic cross-sectional view for explaining a process of transferring a light emitting element in a manufacturing method of a display device according to one embodiment of the present disclosure.

### BEST MODE FOR DISCLOSURE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

Semiconductor light emitting elements described herein conceptually include LEDs, micro-LEDs, etc., and such terms may be used interchangeably.

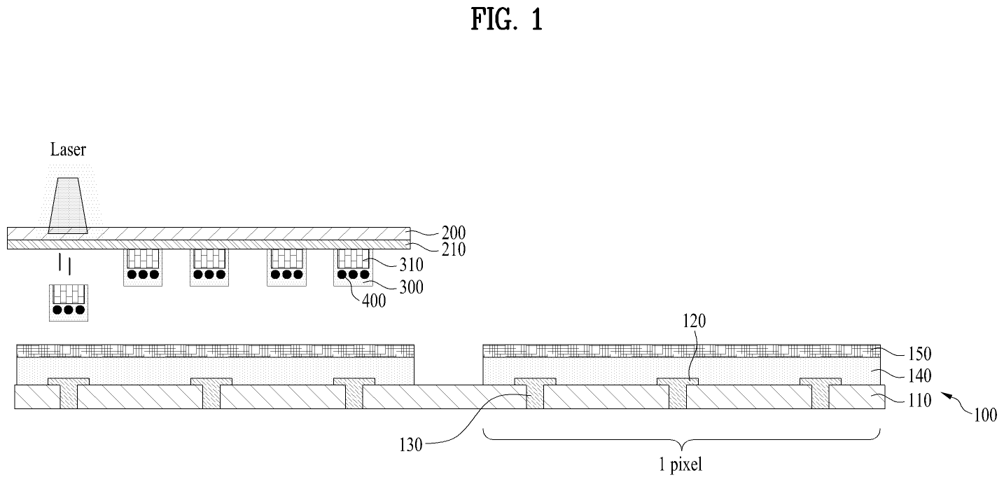

FIG. 1 is a schematic cross-sectional view showing a transfer process of a first light emitting element in a manufacturing method of a display device according to a first embodiment of the present disclosure.

Referring to FIG. 1, after an assembly of a wiring substrate 100 in which a shock-absorbing layer 150 is formed on a substrate 110 provided with electrode pads 120 is prepared, and a light emitting element (for example, a first light emitting element 310) arranged on a base substrate 200 is located at the position of the electrode pad 120 on the assembly, a process of transferring the light emitting element 310 onto the shock-absorbing layer 150 is performed.

By this process, the first light emitting element 310 arranged on the base substrate 200 may be transferred onto the wiring substrate 100 in a non-contact manner.

This non-contact transfer method may be a transfer method performed in a state in which the first light emitting element 310 and the electrode pad 120 are spaced apart from each other.

Here, the first light emitting element 310 is separated from the base substrate 200 and transferred to the electrode pad 120 by a laser lift-off (LLO) method.

That is, the process of transferring the first light emitting element 310 onto the shock-absorbing layer 150 may include irradiating the first light emitting element 310 with a laser from the base substrate 200 side.

When the first light emitting element 310 is irradiated with the laser from the base substrate 200 side, the base substrate 200 or a sacrificial layer 210 and the first light emitting element 310 may be separated from each other at the interface therebetween.

For example, if the base substrate 200 is a growth substrate for the first light emitting element 310, a semiconductor material forming the first light emitting element 310 may be decomposed so that the first light emitting element 310 may be separated from the base substrate 200.

As another example, if the base substrate 200 is not a growth substrate for the first light emitting element 310, the sacrificial layer 210 may be located between the base substrate 200 and the first light emitting element 310. The first light emitting element 310 may be attached to the sacrificial layer 210. If the first light emitting element 310 is a red light emitting element that emits red light, the first light emitting element 310 may be generally grown on a gallium arsenide (GaAs) substrate. However, since the gallium arsenide substrate is not transparent to laser light, in this case, the first light emitting element 310 may be separated from the growth substrate and attached to the sacrificial layer 210. Hereinafter, a case in which the first light emitting element 310 is a red light emitting element will be described as an example.

In this way, the first light emitting element 310 may attached to the sacrificial layer 210 may be separated from the sacrificial layer 210 by the laser. That is, the first light emitting element 310 attached to the sacrificial layer 210 may be separated from the sacrificial layer 210 by the laser lift-off method. At this time, the sacrificial layer 210 may include a material that is capable of absorbing laser light. For example, the sacrificial layer 210 may include a UV absorbing layer. For example, the sacrificial layer 210 may be formed as the UV absorbing layer.

At this time, the semiconductor material may be decomposed to generate gas. That is, gas may be locally generated between the first light emitting element 310 and the base substrate 200 by the laser lift-off process, and the first light emitting element 310 may fall toward the electrode pad 120 with strong energy due to this gas. That is, the first light emitting element 310 may fall at a speed higher than the speed caused by gravity.

The first light emitting element 310 that falls with such strong energy reaches the shock-absorbing layer 150. At this time, the falling first light emitting element 310 can be placed on the shock-absorbing layer 150 by absorbing shock from the falling first light emitting element 310 by the shock-absorbing layer 150.

Here, a protective cap 300 for protecting the first light emitting element 310 may be located on the outer surface of the first light emitting element 310. Such a protective cap 300 may be coated on the outer surface of the first light emitting element 310 to prevent the first light emitting element 310 from being damaged during the transfer process. Further, this protective cap 300 may also coat conductive balls 400 for electrically connecting the first light emitting element 310 to the electrode pad 120.

The shock-absorbing layer 150 may include a nano-fiber layer. That is, the shock-absorbing layer 150 may be formed as the nano-fiber layer. In addition, the shock-absorbing layer 150 may have adhesiveness. Therefore, the shock-absorbing layer 150 may absorb shock from the falling first light emitting element 310 and allow the first light emitting element 310 to be placed thereon without bouncing off from a dropped position.

This shock-absorbing layer 150 may be a fiber layer having nanometer-scale pores. For example, the size of the pores of the shock-absorbing layer 150 may be approximately 60 to 80 nm.

An adhesive layer 140 may be located between the shock-absorbing layer 150 and the electrode pads 120. Specifically, the adhesive layer 140 may be located between the shock-absorbing layer 150 and the wiring substrate 100 provided with the electrode pads 120. For example, the shock-absorbing layer 150 may be attached to the electrode pads 120 by the adhesive layer 140.

The shock-absorbing layer 150 and the adhesive layer 140 may have the same directional characteristics with respect to heat. For example, the shock-absorbing layer 150 and the adhesive layer 140 may have the same thermal characteristics, and when heat is applied, a reaction in the same direction may occur. For example, when heat is applied, both the shock-absorbing layer 150 and the adhesive layer 140 are partially or completely liquefied and then hardened. In addition, the shock-absorbing layer 150 and the adhesive layer 140 may be hardened into one layer when heat is applied.

The electrode pads 120 arranged on the wiring substrate 100 may be connected to signal electrodes (or data electrodes; not shown). The electrode pads 120 or the signal electrodes may be connected to a TFT layer 130 provided with thin film transistors (TFTs). A detailed description thereof will be omitted.

As described above, the first light emitting element 310 may be electrically connected to the electrode pad 120 by the conductive balls 400. The transfer process may be performed in a state in which the conductive balls 400 are attached to the first light emitting element 310.

A plurality of first light emitting elements 310 may be grown on or attached to the base substrate 200. The first light emitting element 310 may be transferred to one predetermined position per pixel.

FIG. 1 shows two pixels, and a predetermined number of the first light emitting elements 310 may be transferred per pixel. For example, one first light emitting element 310 may be transferred per pixel at the same time. Although FIG. 1 shows a state in which the first light emitting element 310 is transferred to one pixel for convenience, the first light emitting elements 310 may be transferred to multiple pixels at the same time.

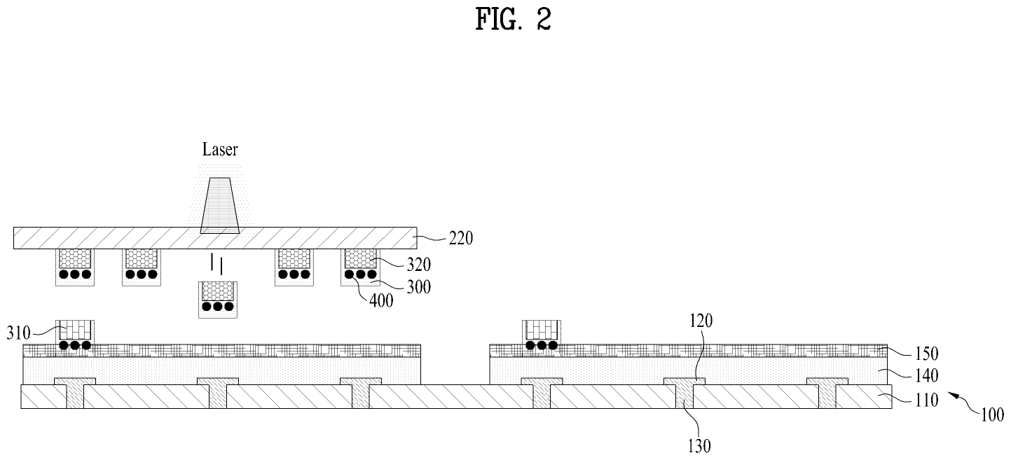

FIG. 2 is a schematic cross-sectional view showing a transfer process of a second light emitting element in the manufacturing method of the display device according to the first embodiment of the present disclosure.

Referring to FIG. 2, after the assembly of the wiring substrate 100 in which the shock-absorbing layer 150 is formed on the substrate 110 provided with the electrode pads 120 is prepared, and a light emitting element (for example, a second light emitting element 320) arranged on a base substrate 200 is located at the position of the electrode pad 120 on the assembly, a process of transferring the light emitting element 320 onto the shock-absorbing layer 150 is performed.

By this process, the second light emitting element 320 arranged on the base substrate 200 may be transferred onto the wiring substrate 100 in the non-contact manner.

This non-contact transfer method may be a transfer method performed in a state in which the second light emitting element 320 and the electrode pad 120 are spaced apart from each other.

Here, the second light emitting element 320 is separated from the base substrate 200 and transferred to the electrode pad 120 by the laser lift-off (LLO) method.

That is, the process of transferring the second light emitting element 320 onto the shock-absorbing layer 150 may include irradiating the second light emitting element 320 with a laser from the base substrate 200 side.

When the second light emitting element 320 is irradiated with the laser from the base substrate 200 side, the base substrate 200 or the sacrificial layer 210 and the second light emitting element 320 may be separated from each other at the interface therebetween.

Here, the second light emitting element 320 may be a green light emitting element 320 that emits green light. Hereinafter, a case in which the second light emitting element 320 is a green light emitting element will be described as an example.

For example, if the base substrate 200 is a growth substrate for the green light emitting element 320, a semiconductor material (for example, a gallium nitride-based semiconductor) forming the green light emitting element 320 may be decomposed so that the green light emitting element 320 may be separated from the base substrate 200.

At this time, the semiconductor material may be decomposed to generate gas. That is, gas (nitrogen gas) may be locally generated between the green light emitting element 320 and the base substrate 200 by the laser lift-off process, and the green light emitting element 320 may fall toward the electrode pad 120 with strong energy due to this gas. That is, the green light emitting element 320 may fall at a speed higher than the speed caused by gravity.

The green light emitting element 320 that falls with such strong energy reaches the shock-absorbing layer 150. At this time, the falling green light emitting element 320 can be placed on the shock-absorbing layer 150 by absorbing shock from the falling second light emitting element 320 by the shock-absorbing layer 150.

Here, the protective cap 300 for protecting the green light emitting element 320 may be located on the outer surface of the green light emitting element 320. Such a protective cap 300 may be coated on the outer surface of the green light emitting element 320 to prevent the green light emitting element 320 from being damaged during the transfer process. Further, this protective cap 300 may also coat the conductive balls 400 for electrically connecting the second light emitting element 320 to the electrode pad 120.

Other matters may be the same as described above with reference to FIG. 1. Therefore, redundant description will be omitted.

Referring to FIG. 2, the transfer process of the green light emitting element 320 may be performed in a state in which the red light emitting element 310 is transferred onto the shock-absorbing layer 150 in one pixel. In this way, a predetermined number of the green light emitting elements 320 may be transferred per pixel in the state in which the red light emitting element 310 is transferred. Although FIG. 2 shows a state in which the green light emitting element 320 is transferred to one pixel for convenience, the green light emitting elements 320 may be transferred to multiple pixels at the same time.

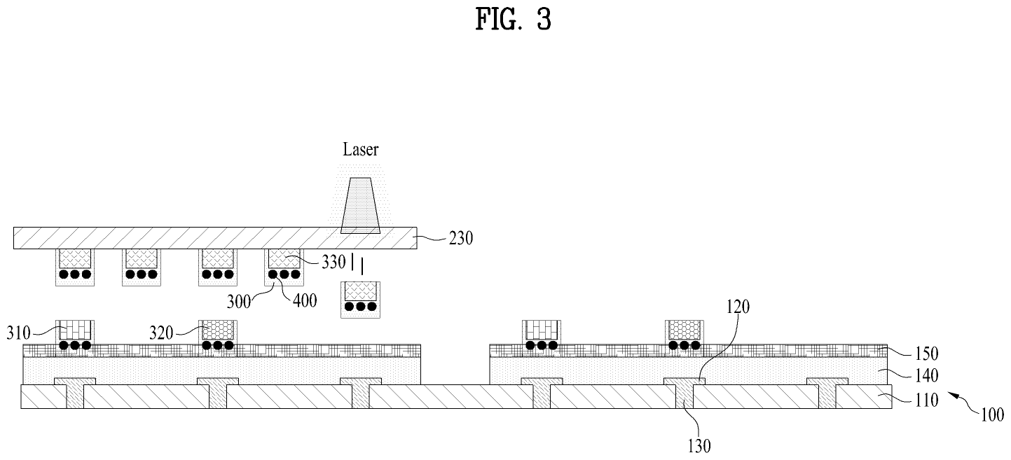

FIG. 3 is a schematic cross-sectional view showing a transfer process of a third light emitting element in the manufacturing method of the display device according to the first embodiment of the present disclosure.

Referring to FIG. 3, after the assembly of the wiring substrate 100 in which the shock-absorbing layer 150 is formed on the substrate 110 provided with the electrode pads 120 is prepared, and a light emitting element (for example, a third light emitting element 330) arranged on a base substrate 200 is located at the position of the electrode pad 120 on the assembly, a process of transferring the light emitting element 330 onto the shock-absorbing layer 150 is performed.

By this process, the third light emitting element 330 arranged on the base substrate 200 may be transferred onto the wiring substrate 100 in the non-contact manner.

This non-contact transfer method may be a transfer method performed in a state in which the third light emitting element 330 and the electrode pad 120 are spaced apart from each other.

Here, the third light emitting element 330 is separated from the base substrate 200 and transferred to the electrode pad 120 by the laser lift-off (LLO) method.

That is, the process of transferring the third light emitting element 330 onto the shock-absorbing layer 150 may include irradiating the third light emitting element 330 with a laser from the base substrate 200 side.

When the third light emitting element 330 is irradiated with the laser from the base substrate 200 side, the base substrate 200 or the sacrificial layer 210 and the third light emitting element 330 may be separated from each other at the interface therebetween.

Here, the third light emitting element 330 may be a blue light emitting element 330 that emits blue light. Hereinafter, a case in which the third light emitting element 330 is a blue light emitting element will be described as an example.

For example, if the base substrate 200 is a growth substrate for the blue light emitting element 330, a semiconductor material (for example, a gallium nitride-based semiconductor) forming the blue light emitting element 330 may be decomposed so that the blue light emitting element 330 may be separated from the base substrate 200.

The blue light emitting element 330 that falls with such strong energy reaches the shock-absorbing layer 150 by the laser lift-off. At this time, the falling blue light emitting element 330 can be placed on the shock-absorbing layer 150 by absorbing shock from the falling third light emitting element 330 by the shock-absorbing layer 150.

Here, the protective cap 300 for protecting the blue light emitting element 330 may be located on the outer surface of the blue light emitting element 330. Such a protective cap 300 may be coated on the outer surface of the blue light emitting element 330 to prevent the blue light emitting element 330 from being damaged during the transfer process. Further, this protective cap 300 may also coat the conductive balls 400 for electrically connecting the third light emitting element 330 to the electrode pad 120.

Other matters may be the same as described above with reference to FIGS. 1 and 2. Therefore, redundant description will be omitted.

Referring to FIG. 3, the transfer process of the blue light emitting element 330 may be performed in a state in which the red light emitting element 310 and the green light emitting element 330 are transferred onto the shock-absorbing layer 150 in one pixel. In this way, a predetermined number of the blue light emitting elements 320 may be transferred per pixel in the state in which the red light emitting element 310 and the green light emitting element 320 are transferred. Although FIG. 3 shows a state in which the blue light emitting element 330 is transferred to one pixel for convenience, the blue light emitting elements 330 may be transferred to multiple pixels at the same time.

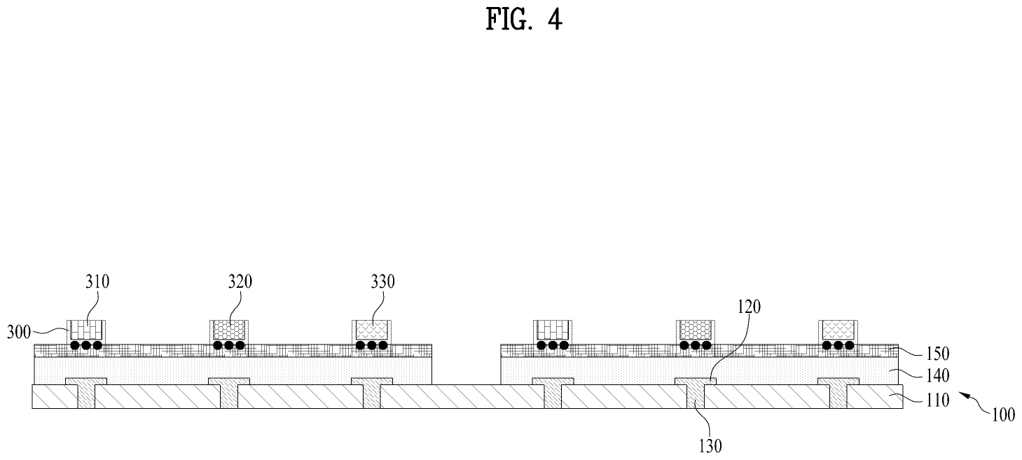

FIG. 4 is a schematic cross-sectional view showing a state in which the transfer of the light emitting elements is completed in the manufacturing method of the display device according to the first embodiment of the present disclosure.

By the process described with reference to FIGS. 1 to 3, the red light emitting element 310, the green light emitting element 320, and the blue light emitting element 330 may be transferred onto the shock-absorbing layer 150 in each pixel.

FIG. 4 shows a state in which the red light emitting element 310, the green light emitting element 320, and the blue light emitting element 330 are transferred and attached to the shock-absorbing layer 150.

Here, the red light emitting element 310, the green light emitting element 320, and the blue light emitting element 330 may be located on the shock-absorbing layer 150 while the conductive balls 400 are attached to the lower surfaces of the red light emitting element 310, the green light emitting element 320, and the blue light emitting element 330. Although not shown, the conductive balls 400 may be attached to first-type electrodes (for example, P-type electrodes) of the red light emitting element 310, the green light emitting element 320, and the blue light emitting element 330.

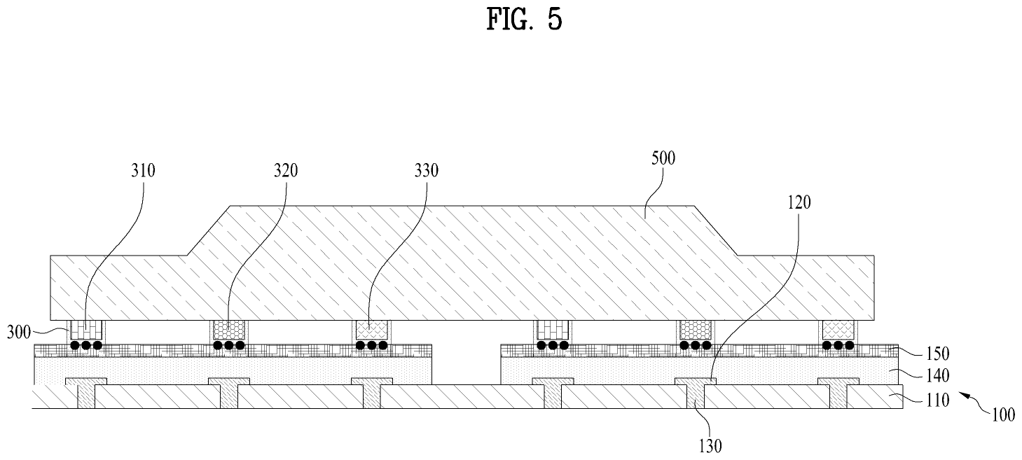

FIG. 5 is a schematic cross-sectional view showing a process of bonding the light emitting elements in the manufacturing method of the display device according to the first embodiment of the present disclosure.

In a state in which the red light emitting element 310, the green light emitting element 320, and the blue light emitting element 330 are transferred onto the shock-absorbing layer 150 in each pixel, a process of bonding the light emitting elements 310, 320, and 330 to the electrode pads 120 may be performed.

Referring to FIG. 5, the light emitting elements 310, 320, and 330 may be bonded to the electrode pads 120 by applying heat in a state in which a pressing member 500 is located on the red light emitting element 310, the green light emitting element 320, and the blue light emitting element 330.

That is, heat may be applied simultaneously with applying pressure to the red light emitting element 310, the green light emitting element 320, and the blue light emitting element 330 using the pressing member 500.

By this process, the red light emitting element 310, the green light emitting element 320, and the blue light emitting element 330 may be electrically connected to the electrode pads 120 by the conductive balls 400.

Although this embodiment describes the process of electrically connecting the light emitting elements 310, 320, and 330 to the electrode pads 120 by the conductive balls 400, the light emitting elements 310, 320, and 330, of course, may be electrically connected to the electrode pads 120 by other electrical connection units than the conductive balls 400. For example, the light emitting elements 310, 320, and 330 may be electrically connected to the electrode pads 120 by a conductive paste, a solder, etc.

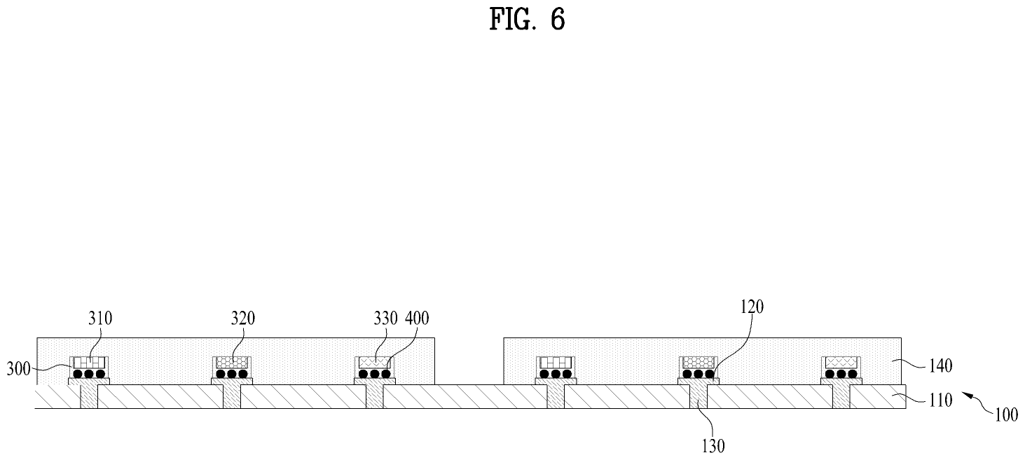

FIG. 6 is a schematic cross-sectional view showing a state in which the assembly

of the light emitting elements is completed by the manufacturing method of the display device according to the first embodiment of the present disclosure.

As described above, when the light emitting elements 310, 320, and 330 are bonded to the electrode pads 120 by applying heat in the state in which the pressing member 500 is located on the red light emitting element 310, the green light emitting element 320, and the blue light emitting element 330, the state shown in FIG. 6 may be achieved.

The electrode pads 120 arranged on the wiring substrate 100 may be connected to the signal electrodes (or the data electrodes; not shown). The electrode pads 120 or the signal electrodes may be connected to the TFT layer 130 provided with the thin film transistors (TFTs). Therefore, each light emitting element 310, 320, or 330 may be driven by switching driving by the TFT layer 130.

For example, if the red light emitting element 310, the green light emitting element 320, and the blue light emitting element 330 are vertical light emitting elements, a scan electrode (or a common electrode; not shown) may be formed on the red light emitting element 310, the green light emitting element 320, and the blue light emitting element 330.

As described above, since the shock-absorbing layer 150 and the adhesive layer 140 may have the same directional characteristics with respect to heat, the shock-absorbing layer 150 and the adhesive layer 140 may be hardened into one layer 140 when heat is applied after this bonding process. That is, a layer indicated by 140 in FIG. 6 may mean a layer into which the adhesive layer 140 and the shock-absorbing layer 150 are combined through hardening thereof. However, in some cases, a part of the shock-absorbing layer 150 may remain.

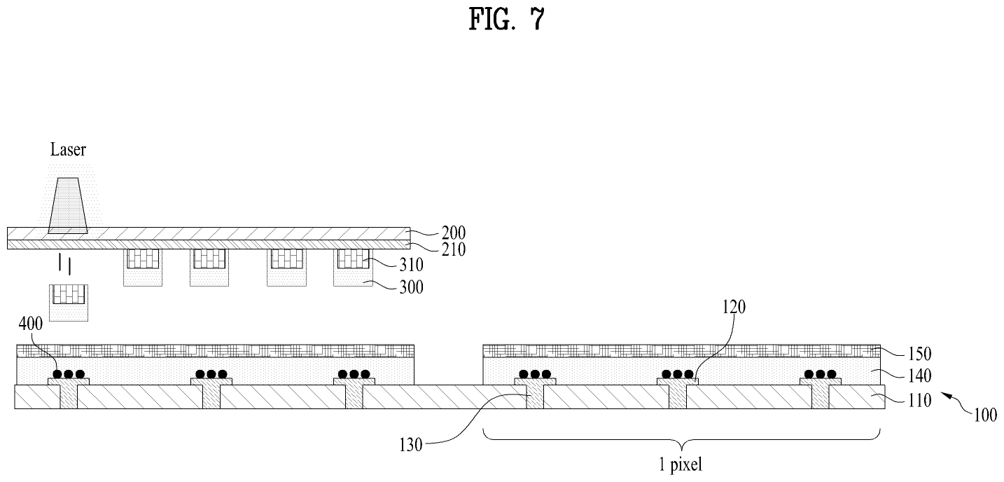

FIG. 7 is a schematic cross-sectional view showing a transfer process of a first light emitting element in a manufacturing method of a display device according to a second embodiment of the present disclosure.

Referring to FIG. 7, according to the second embodiment, after an assembly of a wiring substrate 100 in which a shock-absorbing layer 150 is formed on a substrate 110 provided with electrode pads 120 is prepared, and a light emitting element (for example, a first light emitting element 310) arranged on a base substrate 200 is located at the position of the electrode pad 120 on the assembly, a process of transferring the light emitting element 310 onto the shock-absorbing layer 150 is performed.

By this process, the first light emitting element 310 arranged on the base substrate 200 may be transferred onto the wiring substrate 100 in the non-contact manner. This non-contact transfer method may be a transfer method performed in a state in which the first light emitting element 310 and the electrode pad 120 are spaced apart from each other.

When the first light emitting element 310 is irradiated with a laser from the base substrate 200 side, the base substrate 200 or a sacrificial layer 210 and the first light emitting element 310 may be separated from each other at the interface therebetween.

If the first light emitting element 310 is a red light emitting element that emits red light, the first light emitting element 310 may be generally grown on a gallium arsenide (GaAs) substrate. However, since the gallium arsenide substrate is not transparent to laser light, in this case, the first light emitting element 310 may be separated from the growth substrate and attached to the sacrificial layer 210. Hereinafter, a case in which the first light emitting element 310 is a red light emitting element will be described as an example.

Here, a protective cap 300 for protecting the first light emitting element 310 may be located on the outer surface of the first light emitting element 310. Such a protective cap 300 may be coated on the outer surface of the first light emitting element 310 to prevent the first light emitting element 310 from being damaged during the transfer process.

The electrode pads 120 arranged on the wiring substrate 100 may be connected to signal electrodes (or data electrodes; not shown). The electrode pads 120 or the signal electrodes may be connected to a TFT layer 130 provided with thin film transistors (TFTs).

In this embodiment, conductive balls 400 for electrically connecting the red light emitting element 310 to the electrode pad 120 may be located on the electrode pad 120. That is, unlike the first embodiment in which the conductive balls 400 together with the protective cap 300 are attached to the red light emitting element 310, in the second embodiment, the conductive balls 400 may be fixedly located on the electrode pad 120.

The conductive balls 400 may be fixed to the electrode pad 120 by an adhesive layer 140, or may be fixed to the electrode pad 120 by a separate layer, such as a paste or a photoresist. Alternatively, a conductive adhesive layer may be used instead of the conductive balls 400. For example, the conductive adhesive layer may be an anisotropic conductive film (ACF), an anisotropic conductive paste, a solution including conductive particles, or the like. The conductive adhesive layer may be configured as a layer that allows electrical interconnection in the Z direction perpendicular to the thickness direction thereof, but has electrical insulation in the horizontal X-Y direction. Therefore, the conductive adhesive layer may be referred to as a Z-axis conductive layer.

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

This embodiment may be the same as the above-described first embodiment, except for the position of the conductive balls 400. Therefore, redundant description will be omitted.

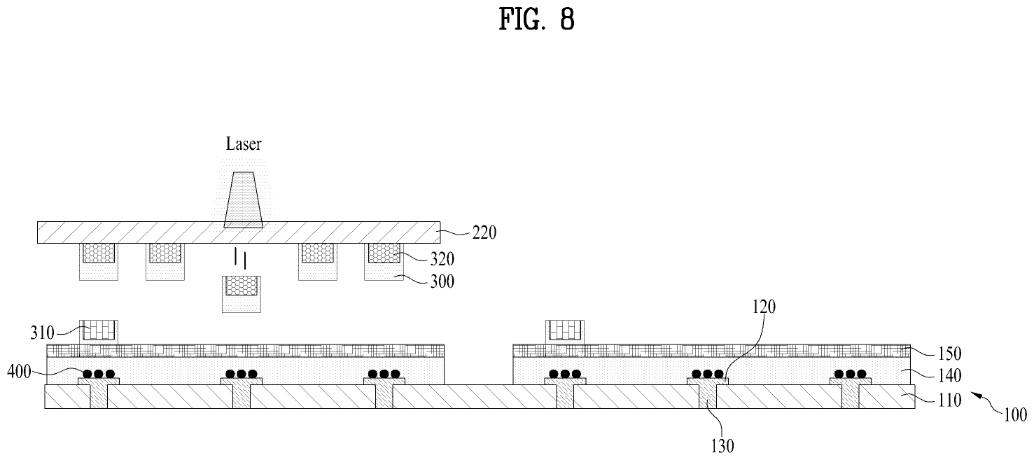

FIG. 8 is a schematic cross-sectional view showing a transfer process of a second light emitting element in the manufacturing method of the display device according to the second embodiment of the present disclosure.

Referring to FIG. 8, after the assembly of the wiring substrate 100 in which the shock-absorbing layer 150 is formed on the substrate 110 provided with the electrode pads 120 is prepared, and a light emitting element (for example, a second light emitting element 320) arranged on a base substrate 200 is located at the position of the electrode pad 120 on the assembly, a process of transferring the light emitting element 320 onto the shock-absorbing layer 150 is performed.

By this process, the second light emitting element 320 arranged on the base substrate 200 may be transferred onto the wiring substrate 100 in the non-contact manner. This non-contact transfer method may be a transfer method performed in a state in which the second light emitting element 320 and the electrode pad 120 are spaced apart from each other.

The process of transferring the second light emitting element 320 onto the shock-absorbing layer 150 may include irradiating the second light emitting element 320 with a laser from the base substrate 200 side.

When the second light emitting element 320 is irradiated with the laser from the base substrate 200 side, the base substrate 200 and the second light emitting element 320 may be separated from each other at the interface therebetween.

Here, the second light emitting element 320 may be a green light emitting element 320 that emits green light. Hereinafter, a case in which the second light emitting element 320 is a green light emitting element will be described as an example.

Here, the protective cap 300 for protecting the green light emitting element 320 may be located on the outer surface of the green light emitting element 320. Such a protective cap 300 may be coated on the outer surface of the green light emitting element 320 to prevent the green light emitting element 320 from being damaged during the transfer process.

In this embodiment, the conductive balls 400 for electrically connecting the green light emitting element 320 to the electrode pad 120 may be located on the electrode pad 120. That is, unlike the first embodiment in which the conductive balls 400 together with the protective cap 300 are attached to the green light emitting element 320, in the second embodiment, the conductive balls 400 may be fixedly located on the electrode pad 120.

The conductive balls 400 may be fixed to the electrode pad 120 by the adhesive layer 140, or may be fixed to the electrode pad 120 by a separate layer, such as a paste or a photoresist. Alternatively, a conductive adhesive layer may be used instead of the conductive balls 400. For example, the conductive adhesive layer may be an anisotropic conductive film (ACF), an anisotropic conductive paste, a solution including conductive particles, or the like. The conductive adhesive layer may be configured as a layer that allows electrical interconnection in the Z direction perpendicular to the thickness direction thereof, but has electrical insulation in the horizontal X-Y direction. Therefore, the conductive adhesive layer may be referred to as a Z-axis conductive layer. Hereinafter, a detailed description thereof will be omitted.

This embodiment may be the same as the above-described first embodiment, except for the position of the conductive balls 400, and the matters described above with reference to FIG. 7. Therefore, redundant description will be omitted.

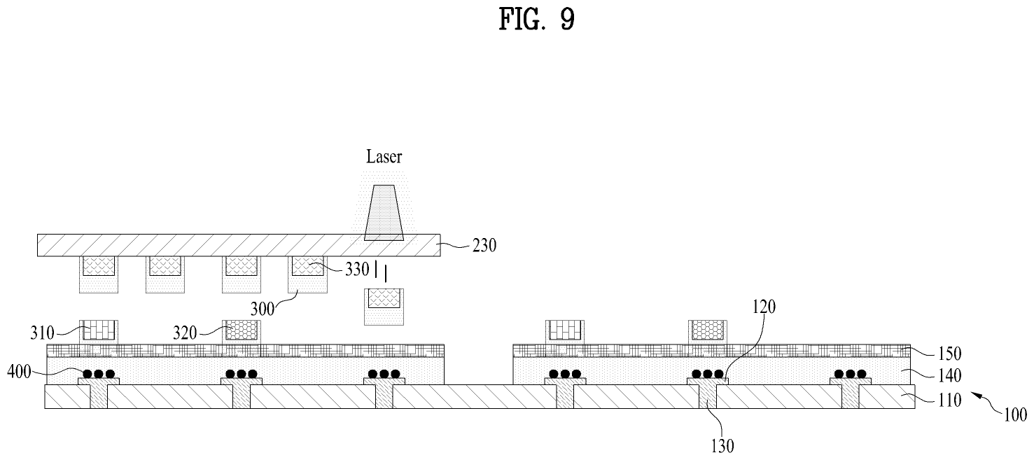

FIG. 9 is a schematic cross-sectional view showing a transfer process of a third light emitting element in the manufacturing method of the display device according to the second embodiment of the present disclosure.

Referring to FIG. 9, after the assembly of the wiring substrate 100 in which the shock-absorbing layer 150 is formed on the substrate 110 provided with the electrode pads 120 is prepared, and a light emitting element (for example, a third light emitting element 330) arranged on a base substrate 200 is located at the position of the electrode pad 120 on the assembly, a process of transferring the light emitting element 330 onto the shock-absorbing layer 150 is performed.

By this process, the third light emitting element 330 arranged on the base substrate 200 may be transferred onto the wiring substrate 100 in the non-contact manner. This non-contact transfer method may be a transfer method performed in a state in which the third light emitting element 330 and the electrode pad 120 are spaced apart from each other.

The process of transferring the third light emitting element 330 onto the shock-absorbing layer 150 may include irradiating the third light emitting element 330 with a laser from the base substrate 200 side.

When the third light emitting element 330 is irradiated with the laser from the base substrate 200 side, the base substrate 200 and the third light emitting element 330 may be separated from each other at the interface therebetween.

Here, the third light emitting element 330 may be a blue light emitting element 330 that emits blue light. Hereinafter, a case in which the third light emitting element 330 is a blue light emitting element will be described as an example.

Here, the protective cap 300 for protecting the blue light emitting element 330 may be located on the outer surface of the blue light emitting element 330. Such a protective cap 300 may be coated on the outer surface of the blue light emitting element 330 to prevent the blue light emitting element 330 from being damaged during the transfer process.

In this embodiment, the conductive balls 400 for electrically connecting the blue light emitting element 330 to the electrode pad 120 may be located on the electrode pad 120. That is, unlike the first embodiment in which the conductive balls 400 together with the protective cap 300 are attached to the blue light emitting element 330, in the second embodiment, the conductive balls 400 may be fixedly located on the electrode pad 120.

The conductive balls 400 may be fixed to the electrode pad 120 by the adhesive layer 140, or may be fixed to the electrode pad 120 by a separate layer, such as a paste or a photoresist. Alternatively, a conductive adhesive layer may be used instead of the conductive balls 400. For example, the conductive adhesive layer may be an anisotropic conductive film (ACF), an anisotropic conductive paste, a solution including conductive particles, or the like. The conductive adhesive layer may be configured as a layer that allows electrical interconnection in the Z direction perpendicular to the thickness direction thereof, but has electrical insulation in the horizontal X-Y direction. Therefore, the conductive adhesive layer may be referred to as a Z-axis conductive layer. Hereinafter, a detailed description thereof will be omitted.

This embodiment may be the same as the above-described first embodiment, except for the position of the conductive balls 400, and the matters described above with reference to FIGS. 7 and 8. Therefore, redundant description will be omitted.

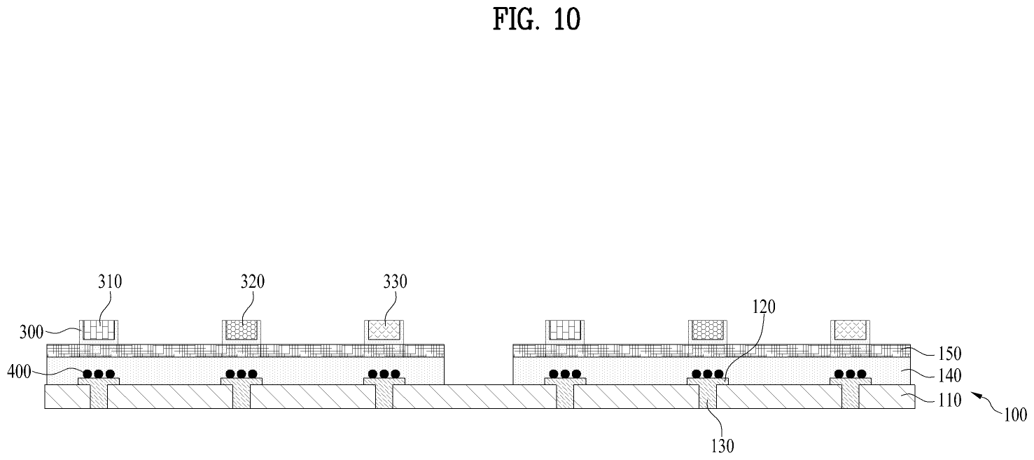

FIG. 10 is a schematic cross-sectional view showing a state in which the transfer of the light emitting elements is completed in the manufacturing method of the display device according to the second embodiment of the present disclosure.

By the process described with reference to FIGS. 7 to 9, the red light emitting element 310, the green light emitting element 320, and the blue light emitting element 330 may be transferred onto the shock-absorbing layer 150 in each pixel.

FIG. 10 shows a state in which the red light emitting element 310, the green light emitting element 320, and the blue light emitting element 330 are transferred and attached to the shock-absorbing layer 150.

Here, as described above, the conductive balls 400 may be fixedly located on the electrode pads 120.

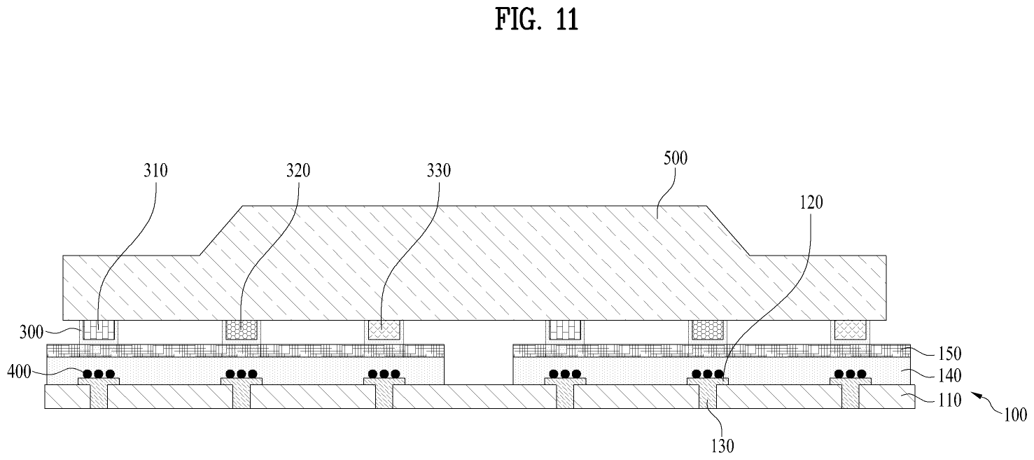

FIG. 11 is a schematic cross-sectional view showing a process of bonding the light emitting elements in the manufacturing method of the display device according to the second embodiment of the present disclosure.

In a state in which the red light emitting element 310, the green light emitting element 320, and the blue light emitting element 330 are transferred onto the shock-absorbing layer 150 in each pixel, a process of bonding the light emitting elements 310, 320, and 330 to the electrode pads 120 may be performed.

Referring to FIG. 11, the light emitting elements 310, 320, and 330 may be bonded to the electrode pads 120 by applying heat in a state in which a pressing member 500 is located on the red light emitting element 310, the green light emitting element 320, and the blue light emitting element 330.

By this process, the red light emitting element 310, the green light emitting element 320, and the blue light emitting element 330 may be electrically connected to the electrode pads 120 by the conductive balls 400 located on the electrode pads 120.

This process may be the same as the matters described in the above-described first embodiment, except for the position of the conductive balls 400. In addition, a state in which the assembly of the light emitting elements manufactured by this process is completed may be the same as the state described above with reference to FIG. 6. Therefore, redundant description will be omitted.

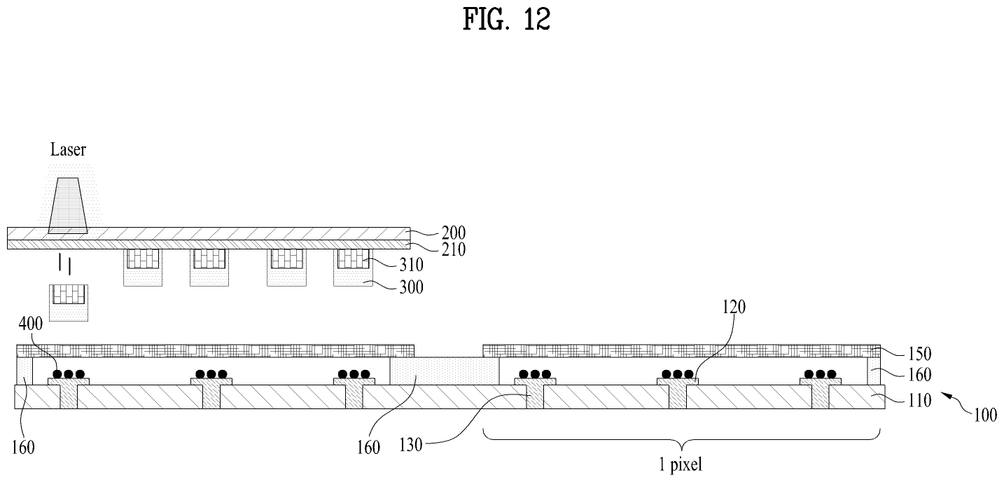

FIG. 12 is a schematic cross-sectional view showing a transfer process of a first light emitting element in a manufacturing method of a display device according to a third embodiment of the present disclosure.

Referring to FIG. 12, according to the third embodiment, after an assembly of a wiring substrate 100 in which a shock-absorbing layer 150 is formed on a substrate 110 provided with electrode pads 120 is prepared, and a light emitting element (for example, a first light emitting element 310) arranged on a base substrate 200 is located at the position of the electrode pad 120 on the assembly, a process of transferring the light emitting element 310 onto the shock-absorbing layer 150 is performed.

Here, the shock-absorbing layer 150 may be located to be spaced apart from the electrode pads 120 in the assembly of the wiring substrate 100. If the shock-absorbing layer 150 is located to be spaced apart from the substrate 110, the possibility of bubble generation caused when the shock-absorbing layer 150 is directly attached to the adhesive layer 140 or the substrate 110 may be eliminated.

In some cases, such bubbles may change the position of the light emitting element 310 transferred to a corresponding position. However, if the shock-absorbing layer 150 is located to be spaced apart from the substrate 110 or the adhesive layer 140, a situation that may occur due to generation of the bubbles may be eliminated in advance.

The shock-absorbing layer 150 may be located to be spaced apart from the substrate 110 or the adhesive layer 140 by partition walls 160 located at the peripheries of pixels. For example, as show in FIG. 12, the partition walls 160 may be located between the individual pixels so that the shock-absorbing layer 150 may be supported by the partition walls 160 located on both sides of the pixels. FIG. 12 shows the arrangement of the partition walls 160 in one direction, but the partition walls 160 may be located to partition the four sides of unit pixels.

By this process, the first light emitting element 310 arranged on the base substrate 200 may be transferred onto the wiring substrate 100 in the non-contact manner.

At this time, when the first light emitting element 310 is irradiated with a laser from the base substrate 200 side, the base substrate 200 or a sacrificial layer 210 and the first light emitting element 310 may be separated from each other at the interface therebetween.

The electrode pads 120 arranged on the wiring substrate 100 may be connected to signal electrodes (or data electrodes; not shown). The electrode pads 120 or the signal electrodes may be connected to a TFT layer 130 provided with thin film transistors (TFTs).

In this embodiment, conductive balls 400 for electrically connecting the red light emitting element 310 to the electrode pad 120 may be located on the electrode pad 120. That is, in the third embodiment, the conductive balls 400 may be fixedly located on the electrode pad 120. However, as in the first embodiment, the conductive balls 400 may be attached to the red light emitting element 310 to configure a similar embodiment. This embodiment may be referred to as a fourth embodiment, and redundant description will be omitted.

The conductive balls 400 may be fixed to the electrode pad 120 by an adhesive layer 140, or may be fixed to the electrode pad 120 by a separate layer, such as a paste or a photoresist. Alternatively, a conductive adhesive layer may be used instead of the conductive balls 400. For example, the conductive adhesive layer may be an anisotropic conductive film (ACF), an anisotropic conductive paste, a solution including conductive particles, or the like. The conductive adhesive layer may be configured as a layer that allows electrical interconnection in the Z direction perpendicular to the thickness direction thereof, but has electrical insulation in the horizontal X-Y direction. Therefore, the conductive adhesive layer may be referred to as a Z-axis conductive layer. Hereinafter, a detailed description thereof will be omitted.

This embodiment may be the same as the above-described second embodiment, except for the configuration of the shock-absorbing layer 150 located to be spaced apart from the substrate 110 or the adhesive layer 140. Therefore, redundant description will be omitted.

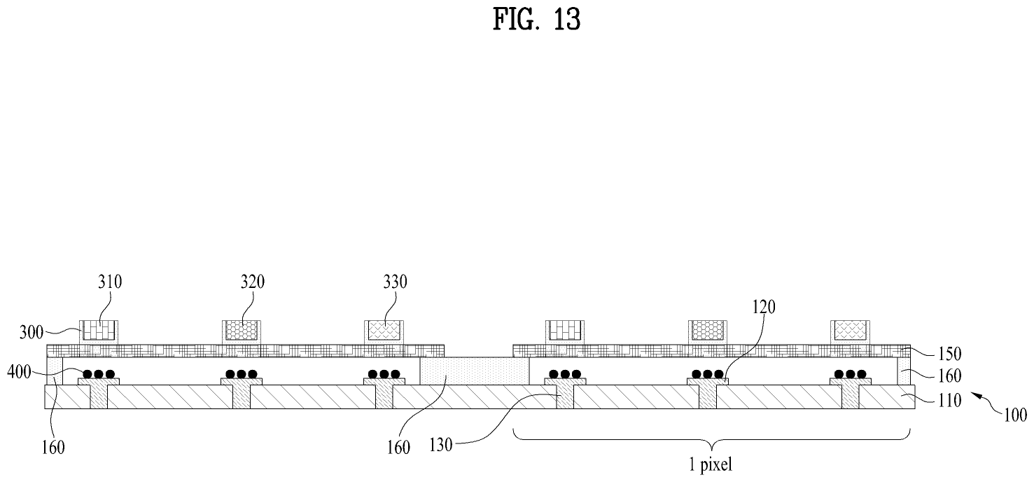

FIG. 13 is a schematic cross-sectional view showing a state in which the transfer of the light emitting elements is completed in the manufacturing method of the display device according to the third embodiment of the present disclosure.

By the process described with reference to FIG. 12, the red light emitting element 310, a green light emitting element 320, and a blue light emitting element 330 may be transferred onto the shock-absorbing layer 150 in each pixel. Here, although the description of transfer processes of the green light emitting element 320 and the blue light emitting element 330 is omitted, the same transfer process as the red light emitting element 310 may be performed.

FIG. 13 shows a state in which the red light emitting element 310, the green light emitting element 320, and the blue light emitting element 330 are transferred and attached to the shock-absorbing layer 150.

Here, as described above, the conductive balls 400 may be fixedly located on the electrode pads 120. In addition, the shock-absorbing layer 150 may be located to be spaced apart from the substrate 110 or the adhesive layer 140 by the partition walls 160 located at the pixel peripheries.

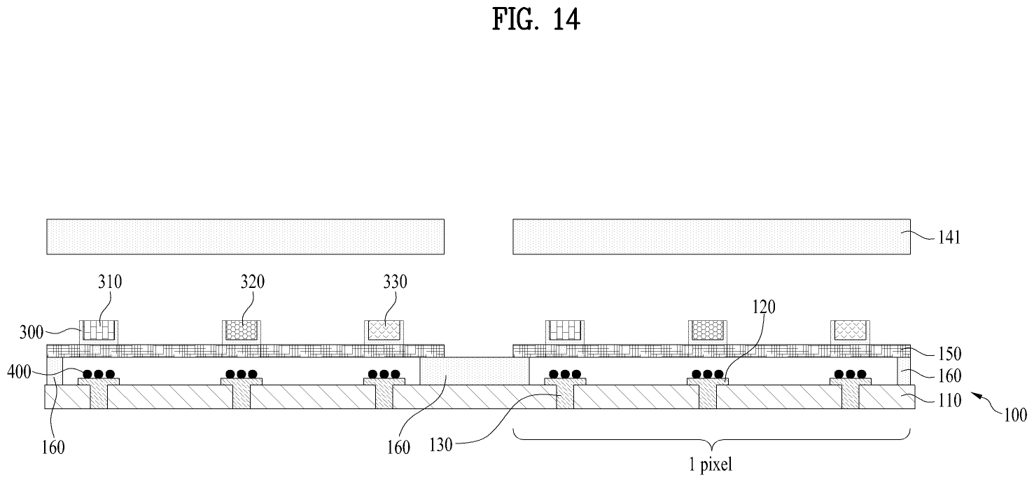

FIG. 14 is a schematic cross-sectional view showing a state in which an adhesive layer is placed in the manufacturing method of the display device according to the third embodiment of the present disclosure.

In each pixel, in the state in which the red light emitting element 310, the green light emitting element 320, and the blue light emitting element 330 are transferred ono the shock-absorbing layer 150, an adhesive layer 141 may be located on the transferred light emitting elements 310, 320, and 330, as shown in FIG. 14. That is, the adhesive layer 141 may be located in each pixel area. The adhesive layer 141 may have substantially the same size or area as the shock-absorbing layer 510 located in each pixel area. However, in some cases, the adhesive layer 141 may, of course, have different area from the shock-absorbing layer 150 located in each pixel area.

The adhesive layer 141 may be bonded to the shock-absorbing layer 150 through a subsequent bonding process to form one layer.

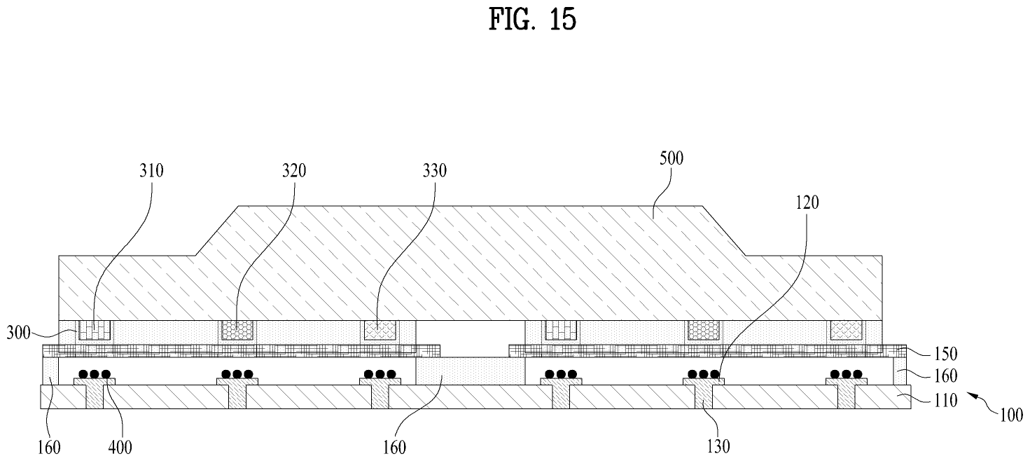

FIG. 15 is a schematic cross-sectional view showing a process of bonding the light emitting elements in the manufacturing method of the display device according to the third embodiment of the present disclosure.

In the state in which the red light emitting element 310, the green light emitting element 320, and the blue light emitting element 330 are transferred onto the shock-absorbing layer 150 in each pixel, a process of bonding the light emitting elements 310, 320, and 330 to the electrode pads 120 may be performed.

Referring to FIG. 15, the light emitting elements 310, 320, and 330 may be bonded to the electrode pads 120 by applying pressure to the adhesive layer 141 toward the light emitting elements 310, 320, and 330.

For example, the light emitting elements 310, 320, and 330 may be bonded to the electrode pads 120 by applying pressure to the adhesive layer 141 and the light emitting elements 310, 320, and 330 together with the shock-absorbing layer 150 toward the light emitting elements 310, 320, and 330 while applying heat in a state in which a pressing member 500 is located on the adhesive layer 141.

By this process, the red light emitting element 310, the green light emitting element 320, and the blue light emitting element 330 may be electrically connected to the electrode pads 120 by the conductive balls 400 located on the electrode pads 120.

The shock-absorbing layer 150 and the adhesive layer 141 may have the same directional characteristics with respect to heat. For example, the shock-absorbing layer 150 and the adhesive layer 141 may have the same thermal characteristics, and when heat is applied, a reaction in the same direction may occur. For example, when heat is applied, both the shock-absorbing layer 150 and the adhesive layer 141 are partially or completely liquefied and then hardened. In addition, the shock-absorbing layer 150 and the adhesive layer 141 may be hardened into one layer when heat is applied.

Therefore, the adhesive layer 141 and the shock-absorbing layer 150 may be formed into one layer 141 by the above-described bonding process.

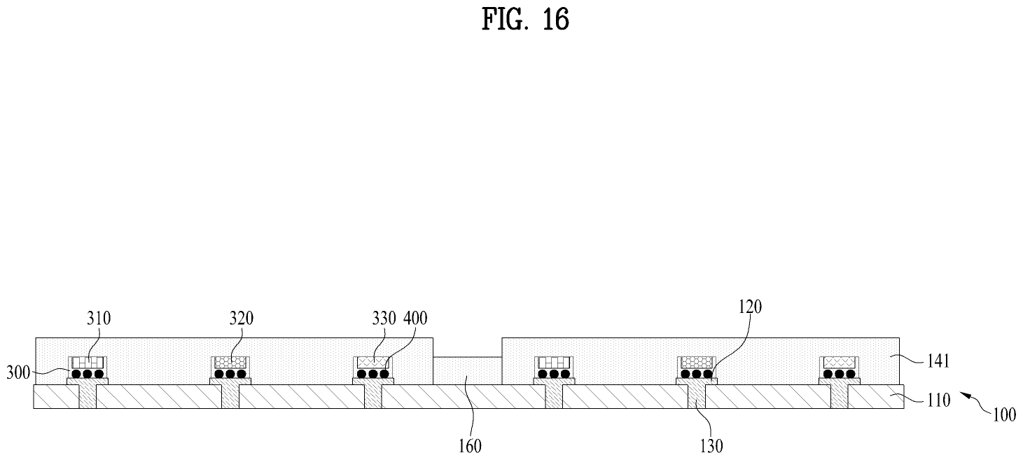

FIG. 16 is a schematic cross-sectional view showing a state in which the assembly of the light emitting elements is completed by the manufacturing method of the display device according to the third embodiment of the present disclosure.

As described above, when the light emitting elements 310, 320, and 330 are bonded to the electrode pads 120 by applying heat in the state in which the pressing member 500 is located on the red light emitting element 310, the green light emitting element 320, and the blue light emitting element 330, the state shown in FIG. 16 may be achieved.

The electrode pads 120 arranged on the wiring substrate 100 may be connected to the signal electrodes (or the data electrodes; not shown). The electrode pads 120 or the signal electrodes may be connected to the TFT layer 130 provided with the thin film transistors (TFTs). Therefore, each light emitting element 310, 320, or 330 may be driven by switching driving by the TFT layer 130.

For example, if the red light emitting element 310, the green light emitting element 320, and the blue light emitting element 330 are vertical light emitting elements, a scan electrode (or a common electrode; not shown) may be formed on the red light emitting element 310, the green light emitting element 320, and the blue light emitting element 330.

As described above, since the shock-absorbing layer 150 and the adhesive layer 141 may have the same directional characteristics with respect to heat, the shock-absorbing layer 150 and the adhesive layer 141 may be hardened into one layer 141 when heat is applied after this bonding process. That is, a layer indicated by 141 in FIG. 16 may mean a layer into which the adhesive layers 141 and the shock-absorbing layer 150 are combined through hardening thereof. However, in some cases, a part of the shock-absorbing layer 150 may remain.

In addition, the partition walls 160 may be located between pieces of the hardened adhesive layer 141 in the pixels.

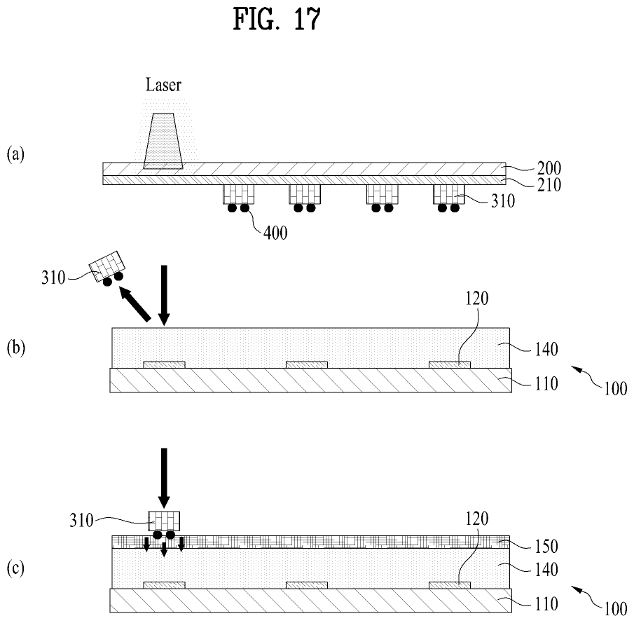

FIG. 17 is a schematic cross-sectional view for explaining a process of transferring a light emitting element in a manufacturing method of a display device according to one embodiment of the present disclosure.

The process of transferring the light emitting element (for example, the first light emitting element 310) arranged on the base substrate 200, as shown in FIG. 17(a), onto the assembly of the wiring substrate 100 on which the adhesive layer 140 is located on the substrate 110 provided with the electrode pads 120 formed thereon, as shown in FIG. 17(b), is illustrated.

As described above, the first light emitting element 310 may be separated from the base substrate 200 and transferred to the electrode pad 120 by the laser lift-off (LLO) method. At this time, the conductive balls 400 may be located under the first light emitting element 310.

As described above with reference to FIG. 1, the first light emitting element 310 may be a red light emitting element 310 that emits red light, and the red light emitting element 310 may be attached to the sacrificial layer 120 and transferred.

In this way, the first light emitting element 310 attached to the sacrificial layer 210 may be irradiated with the laser to be separated from the sacrificial layer 210. At this time, the semiconductor material may be decomposed to generate gas. That is, gas may be locally generated between the first light emitting element 310 and the base substrate 200 by the laser lift-off process, and the first light emitting element 310 may fall toward the electrode pad 120 with strong energy due to this gas. That is, the first light emitting element 310 may fall at a speed higher than the speed caused by gravity.

The first light emitting element 310 that falls with such strong energy may not be placed on the adhesive layer 140, and may bounce off, as shown in FIG. 17(b). In addition, the first light emitting element 310 may be damaged in the process of bouncing off after hitting the adhesive layer 140.

This problem may be identically applied to the second light emitting element 320 and the third light emitting element 330 that are respectively grown on the growth substrate and undergo the transfer process.

However, as shown in FIG. 17(c), if the shock-absorbing layer 150 is provided on the wiring substrate 100, the first light emitting element 310 separated from the base substrate 200 by the transfer process reaches the shock-absorbing layer 150. Here, the falling first light emitting element 310 may be placed on the shock-absorbing layer 150 by absorbing shock from the falling first light emitting element 310 by the shock-absorbing layer 150.

In some cases, the shock-absorbing layer 150 may work together with the adhesive layer 140 to absorb the shock from the falling first light emitting element 310.

Therefore, during the non-contact transfer process, the shock from the first light emitting element 310 may be absorbed to prevent the first light emitting element 310 from bouncing off, thereby preventing damage to the first light emitting element 310.

Since the transfer process described above may be performed in one step, the light emitting elements 310, 320, and 330 located on the respective base substrates 200 may be directly transferred onto the wiring board 100. For example, in a state in which the light emitting elements 310, 320, and 330 are formed on the base substrates 200, the so-called chip-on-wafer (COW) state, the transfer process may be performed once.

Therefore, the process of electrically connecting the light emitting elements 310, 320, and 330 to the wiring substrate 100 may be performed immediately thereafter.

In addition, high-precision alignment of the light emitting elements 310, 320, and 330 may be achieved by this process.

In addition, since the transfer process and electrical connection process of the light emitting elements 310, 320, and 330 are simplified, a yield may be improved. Accordingly, the manufacturing cost and production time of the display device may be significantly reduced.

This transfer process may be used for display devices having all resolutions regardless of the pixel pitch of a display. Here, a time for performing laser lift-off may be adjusted.

In addition, since the above-described transfer process may be performed in the non-contact manner, the interaction between materials is minimized, thereby enabling active response to improve a mass production yield.

This transfer process may be applied to all vertical, horizontal, and flip-chip light emitting elements. In addition, as described above, red light emitting elements may be attached to the base substrate and transferred under the same conditions as green and blue light emitting elements located on the growth substrate.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL APPLICABILITY

According to the present disclosure, a display device using semiconductor light emitting elements, such as micro-LEDs, may be provided.

What is claimed is:

1. A manufacturing method of a display device using light emitting elements comprising:
preparing an assembly comprising a wiring substrate on which electrode pads are formed, and a shock-absorbing layer which is formed on the wiring substrate;
locating the light emitting elements arranged on a base substrate at positions of the electrode pads on the assembly;
transferring the light emitting elements onto the shock-absorbing layer; and
bonding the light emitting elements to the electrode pads.

2. The manufacturing method according to claim 1, wherein the light emitting elements are electrically connected to the electrode pads by conductive balls.

3. The manufacturing method according to claim 1, wherein transferring the light emitting elements onto the shock-absorbing layer comprises irradiating a laser on the light emitting elements from a base substrate side.

4. The manufacturing method according to claim 1, wherein an adhesive layer is located between the electrode pads and the shock-absorbing layer.

5. The manufacturing method according to claim 4, wherein the shock-absorbing layer and the adhesive layer have the same directional characteristics with respect to heat.

6. The manufacturing method according to claim 1, wherein the shock-absorbing layer comprises a nano-fiber layer.

7. The manufacturing method according to claim 1, wherein the base substrate comprises a growth substrate for the light emitting elements.

8. The manufacturing method according to claim 7, wherein the light emitting elements grown on the growth substrate are blue or green light emitting elements.

9. The manufacturing method according to claim 1, wherein the base substrate comprises a sacrificial layer to which the light emitting elements are attached.

10. The manufacturing method according to claim 9, wherein the sacrificial layer comprises a UV absorbing layer.

11. The manufacturing method according to claim 9, wherein the light emitting elements attached to the sacrificial layer are red light emitting elements.

12. The manufacturing method according to claim 1, wherein bonding the light emitting elements to the electrode pads comprises applying heat and pressure.

13. A manufacturing method of a display device using light emitting elements comprising:
preparing an assembly comprising a wiring substrate on which electrode pads is formed, and a shock-absorbing layer which is located on the wiring substrate;
locating the light emitting elements arranged on a base substrate at positions of the electrode pads on the assembly;
transferring the light emitting elements onto the shock-absorbing layer;
locating an adhesive layer on the transferred light emitting elements; and
bonding the light emitting elements to the electrode pads by applying pressure to the adhesive layer toward the light emitting elements.

14. The manufacturing method according to claim 13, wherein the light emitting elements are electrically connected to the electrode pads by conductive balls located on the electrode pads.

15. The manufacturing method according to claim 13, wherein the assembly comprises partition walls configured to support the shock-absorbing layer to space the shock-absorbing layer apart from the electrode pads.

16. The manufacturing method according to claim 13, wherein transferring the light emitting elements onto the shock-absorbing layer comprises irradiating a laser on the light emitting elements from a base substrate side.

17. The manufacturing method according to claim 13, wherein the shock-absorbing layer comprises a nano-fiber layer.

18. The manufacturing method according to claim 13, wherein the shock-absorbing layer and the adhesive layer have the same directional characteristics with respect to heat.

19. The manufacturing method according to claim 13, wherein the base substrate comprises a sacrificial layer to which the light emitting elements are attached.

20. The manufacturing method according to claim 19, wherein the sacrificial layer comprises a UV absorbing layer.
